(19) United States
(12) Patent Application Publication
(10) Pub. No.: US 2025/0053095 A1
(43) Pub. Date: Feb. 13, 2025

(54) A METHOD AND APPARATUS FOR IMPROVING THE UNIFORMITY OF EXPOSURE OF A PERIODIC PATTERN

(71) Applicant: EULITHA A.G., Würenlos (CH)

(72) Inventors: Francis CLUBE, Windisch (CH); Harun SOLAK, Untersiggenthal (CH)

(21) Appl. No.: 18/722,750

(22) PCT Filed: Dec. 22, 2022
(86) PCT No.: PCT/IB2022/062683

§ 371 Date: Jun. 21, 2024

(30) Foreign Application Priority Data
Dec. 22, 2021 (US) 63292504

(51) Int. Cl. G03F 7/00; G03F 7/20

(52) U.S. Cl. CPC G03F 7/70408; G03F 7/201; G03F 7/70325; G03F 7/7035

(57) ABSTRACT

A method and an apparatus for improving the uniformity of exposure of a first periodic pattern in a photomask by a collimated beam of monochromatic light in a photolithographic system that prints a second periodic pattern into a photosensitive layer on a substrate that is in proximity to the photomask, include providing a plate that is composed of a material transparent to the beam and that has opposing surfaces that are parallel and separated by a thickness. The plate is arranged in the photolithographic system such that the beam illuminates the plate at an initial angle of incidence and the beam transmitted by the plate illuminates the photomask. The plate is rotated by at least one angle about at least one axis of rotation during the exposure such that the transmitted beam displaces translationally across the photomask.

Photolithographic exposure of periodic patterns using the Talbot effect, or Talbot imaging, is well-known in the prior art. For example, in Zanke et al., “Large-area patterning for photonic crystals via coherent diffraction lithography”, J. Vac. Sci. Technol. B22(6), 2004, a hexagonal lattice of elliptical holes with a spatial period of 583 nm is formed in a chrome mask and illuminated at normal incidence by plane-wave illumination at a wavelength of 193 nm. The periodic pattern in the mask diffracts the beam and at certain, periodic distances from the mask, which are separated by a so-called Talbot distance, the diffracted orders interfere to reproduce the pattern in the mask. By placing a photoresist-coated substrate at one of these “self-image” planes, the periodic pattern of the mask is printed into the photoresist.

U.S. Pat. No. 8,841,046 discloses two further related photolithographic methods based on Talbot imaging for printing a one-dimensional or two-dimensional array of periodic or quasi-periodic features onto a photoresist-coated substrate. Quasi-periodic refers to periodic patterns whose period varies slowly over the area of the pattern such that the local period (over a distance of similar size to the separation between the mask and substrate) is substantially constant. It further discloses that the methods can be applied to periodic patterns of line features that are curved. In the first of these two methods, a periodic or quasi-periodic pattern in a mask is illuminated by a beam of collimated light from a source having a broad spectral bandwidth, and the substrate is positioned at a distance from the mask at which the Talbot effect produces a transversal intensity distribution that becomes “stationary”, that is, invariant to further increase in distance from the mask. In Solak et al., “Achromatic spatial frequency multiplication: A method for production of nanometer-scale periodic features”, J. Vac. Sci. Technol. B23(6), 2005) it is shown that this distance is related to the spectral bandwidth, Δλ, by

$$d \approx \frac{k {Λ}^{2}}{Δ λ}$$

where Λ is the period of the pattern and k is a constant.

In the second method, the periodic or quasi-periodic pattern in the mask is illuminated by a beam of collimated monochromatic light, and the distance between the mask and the substrate is varied during the exposure by a distance corresponding to an integer multiple of the Talbot distance. This prints an average of the transverse intensity distribution formed between successive Talbot image planes, resulting in a periodic distribution that has practically unlimited depth of focus. The disclosure further teaches that the distance between the mask and substrate may be varied during exposure either continuously over the range required or may be varied in a discrete way by exposing the plate at multiple positions.

These two methods are commonly referred to as respectively “Achromatic Talbot lithography” (ATL) and “Displacement Talbot lithography” (DTL).

U.S. Pat. No. 8,525,973 discloses a modification of the DTL technique that allows a plurality of periodic patterns in a mask that have different values of period to be simultaneously printed into a photosensitive layer.

For a periodic pattern to be printed uniformly using any of above Talbot-effect-based methods, it is generally important that the intensity of the beam illuminating the mask is uniform (typically <±3% variation) over the pattern area. It is additionally important that the beam is well collimated, that is, the rays illuminating each localised area of the mask are accurately parallel. If they are not, then rays at different angles project Talbot images in different directions after the mask, which then smear, or blur, the resultant image formed at the substrate, thus degrading the resolution of the printed pattern. The degree of collimation required depends on the period of the pattern and the distance between the mask and substrate. For sub-micron periods and a mask-substrate separation of ˜0.1 mm, the degree of collimation required is typically ˜1 mR. Examples of optical systems devised for generating such beams with uniform intensity and good collimation from suitable monochromatic and broad-band light sources for respectively DTL and ATL applications are disclosed in, for example, U.S. Pat. Nos. 8,525,973 and 10,365,566, and U.S. patent application Ser. No. 14/123,330.

A disadvantage of the high-collimation requirement, especially using monochromatic light, is that the intensity uniformity of the beam illuminating the mask is sensitive to small imperfections or defects, typically of size ˜0.1-1 mm, in or on the optical components of the illumination system that forms the beam. Such an imperfection, for example a microbubble inside a lens, a dig or particle on the lens surface or a fine scratch (whose dimension is small in one direction) can project a shadow or other perturbation in the beam illuminating the mask, resulting in a localised region of significantly different intensity. In other words, not only does the high-collimation requirement of the Talbot effect prevent the smearing out of the periodic pattern illuminating the photoresist, it also prevents the smearing out of inhomogeneities of intensity in the illumination beam caused by small defects in the beam-forming optics. Depending on the nature of the defect, for example, whether it affects the amplitude and/or phase of the immediately transmitted light, it may form a dark or bright spot, or set of concentric rings with alternating higher and lower intensity in the beam illuminating the mask. The size of the resulting undesirable inhomogeneity at the mask depends on the size of the defect and degree of collimation but is typically in the range 0.1-5 mm, and the contrast of the defect in relation to the intensity of the surrounding beam is typically in the range 1-20%. These inhomogeneities in the intensity distribution illuminating the mask produce corresponding inhomogeneities in the energy density distribution that exposes the mask over the duration of the exposure, which results in corresponding inhomogeneities in the sizes of the periodic features of the DTL-printed pattern. Depending on the application concerned, such local inhomogeneities in the printed pattern can be unacceptable.

Another disadvantage of an exposure beam with highly collimated and monochromatic light, as is required by both conventional Talbot-imaging lithography and DTL, is that the intensity distribution of the beam illuminating the mask is also degraded by general scatter from the optics of the beam-forming system, in particular scatter from micro- and nano-scale roughness of lens surfaces that is present even with good-quality polishing. The combination of general scatter from the optics and light that has both high temporal and spatial coherence produces a ubiquitous pattern of speckle in beam illuminating the mask. Speckle can also be described as a distribution of localized intensity inhomogeneities but is present over the complete beam. The size of the individual speckles is determined by the beam's collimation and is typically in the range 0.5-5 mm, and the contrast of the individual speckles in relation to the mean intensity of the surrounding beam is typically in the range 0.5-10%.

Of course, these problems of localised intensities inhomogeneities may be avoided by using perfect optical elements without any surface or internal imperfections and by ensuring that no particles settle on any of the optics. This, however, can be unrealistic and/or result in very expensive optics, especially if there are many large-diameter elements in the beam-forming system.

Another photolithographic method that requires a beam of collimated and monochromatic light with high uniformity of intensity for illuminating a periodic pattern in the mask, and which is therefore similarly sensitive to imperfections in or on the optical elements of the illumination system, is near-field holographic lithography. Such a method is employed in, for example, Tennant et al., “Characterization of near-field holography grating masks for optoelectronics fabricated by electron beam lithography”, J. Vac. Sci. Technol. B10(6), 1992. According to this method, the beam of collimated, monochromatic light does not illuminate the mask at normal incidence but at an oblique angle that is selected in relation to the period of a linear grating in the mask and the wavelength of illumination such that only the 0^{th} diffraction order and one 1^{st} order propagate after the mask at angles of diffraction that are preferably symmetrically disposed either side of the normal to the mask. The grating in the mask is preferably a phase grating that is designed and fabricated so that the intensities of the two transmitted orders are substantially the same. By so doing, the two diffraction orders interfere in the near-field region after the mask to produce a periodic high-contrast intensity distribution whose planes of respectively high and low intensity are normal to the mask and whose transverse distribution replicates the grating pattern in the mask. By placing a photoresist-coated layer on substrate in proximity to the mask, the grating pattern of the mask is essentially copied into the layer.

It is therefore a first object of the present invention to provide a method for improving the uniformity of exposure of a first periodic pattern in a photomask by a collimated beam in a photolithographic system that uses the Talbot effect to print a second periodic pattern into a photosensitive layer on a substrate that is in proximity to the photomask. In particular, it is an object of the present invention to provide a method for reducing the contrast of localised inhomogeneities in the energy density distribution exposing the first periodic pattern in the photomask that are caused by small imperfections or defects in or on the optical elements of the beam-forming system.

It is a second object of the present invention to provide an apparatus for improving the uniformity of exposure of a first periodic pattern in a photomask by a collimated beam in a photolithographic system that uses the Talbot effect to print a second periodic pattern into a photosensitive layer on a substrate that is in proximity to the photomask. In particular, it is an object of the present invention to provide an apparatus for reducing the contrast of localised inhomogeneities in the energy density distribution exposing the first periodic pattern in the photomask that are caused by small imperfections or defects in or on the optical elements of the beam-forming system.

It is a third object of the present invention to provide an apparatus for improving the uniformity of exposure of a first periodic pattern in a photomask by a collimated beam of monochromatic light in a photolithographic system that prints a second periodic pattern into a photosensitive layer on a substrate that is in proximity to the photomask. In particular, it is an object of the present invention to provide an apparatus for reducing the contrast of localised inhomogeneities in the energy density distribution exposing the first periodic pattern in the photomask that are caused by small imperfections or defects in or on the optical elements of the beam-forming system.

According to a first aspect of the present invention, a method is provided for improving the uniformity of exposure of a first periodic pattern in a photomask by a collimated beam in a photolithographic system that uses the Talbot effect to print a second periodic pattern into a photosensitive layer on a substrate that is in proximity to the photomask, which method comprises:
a) providing a plate that is composed of a material transparent to the beam and that has parallel opposing surfaces separated by a thickness;
b) arranging said plate in the photolithographic system such that the beam illuminates the plate at an initial angle of incidence and the beam transmitted by the plate illuminates the photomask; and
c) rotating said plate by at least one angle about at least one axis of rotation during the exposure such that the transmitted beam displaces translationally across the photomask.

Preferably, said plate is rotated about a single axis of rotation that is either perpendicular or parallel to the direction of the beam.

Advantageously, the plate is arranged so that the beam illuminates it at an oblique initial angle of incidence and the plate is rotated by an angle about an axis of rotation that is parallel to the direction of the beam. Preferably, the oblique angle of incidence is >5° and most preferably >10°, and the angle by which the plate is rotated is preferably a whole number of 360° rotations.

Preferably, the transmitted beam is displaced translationally across the photomask by a distance that is larger than the maximum spatial extent, or size, of the inhomogeneities of exposure energy density and, most preferably, by a distance that is larger than 5 times the maximum spatial extent, or size, of the inhomogeneities.

Preferably the plate is arranged in the photolithographic system such that it is stationary at the start of the exposure and so that the beam illuminates it at a particular, or selected, initial angle of incidence; or, alternatively, it is rotating about the at least one axis of rotation before the exposure such that at the start of the exposure the beam illuminates the plate at an initial angle of incidence that is either selected or within a selected range of angles.

Advantageously, the rotation of the plate about at least one axis of rotation is a continuous motion throughout the duration of the exposure. Alternatively, it may be a stepping motion in which the plate is stationary, or at least has slower speed, between successive steps of a sequence of rotational steps.

Optionally, the step of rotating said plate by at least one angle about at least one axis of rotation during the exposure such that the transmitted beam is displaced translationally across the photomask is repeated once or a plurality of times during the exposure.

Preferably, the thickness, the initial angle of incidence, the at least one angle of rotation and the at least one axis of rotation are selected so that the resulting translational displacement of the beam across the photomask is larger than the size, in at least one direction, of local inhomogeneities of intensity in the exposure beam, and most preferably at least 5 times as large, whereby the contrast of the time-integrated intensity distribution produced by the displacement of the local inhomogeneity illuminating the photomask is correspondingly reduced. For example, if the inhomogeneity is an elongated striation, then the resulting translational displacement should be at least as large as the width (rather than the length) of the elongated striation whereby the contrast of the time-intensity distribution is reduced by a factor of at least 2, and most preferably at least 5 times the width whereby the contrast of the time-intensity distribution is reduced by a factor of at least 5.

Preferably, the transparency of the plate is such that the internal transmission of the plate (i.e. ignoring surface reflections) is greater than >90%, and most preferably >98%.

The parallelism of the opposing surfaces of the plate that is provided is such that the variation of the angle of incidence of the transmitted beam at the photomask produced by rotating said plate by the at least one angle about the at least one axis of rotation during the exposure is sufficiently small so that the resulting lateral displacement of the intensity distribution exposing the photosensitive layer does not unacceptably blur and degrade the contrast of the second periodic pattern printed in the layer. Preferably, the lateral displacement of the intensity distribution illuminating the photosensitive layer (neglecting any change in shape of the intensity distribution at the layer produced by a change in separation of the photomask and substrate performed according to DTL) is less than 1/10 of the period of the second periodic pattern, and most preferably less than 1/20 of the period of the second periodic pattern.

The first periodic pattern in the photomask and the corresponding second periodic pattern printed into the photosensitive layer on the substrate are either one-dimensional periodic patterns, that arrays of alternating line and space features, or alternatively two-dimensional array of features, such as features arranged on a hexagonal grid or features arranged on a square grid.

The first periodic pattern in the mask is preferably formed as a phase mask in which the individual features of the periodic pattern modify the phase of the locally transmitted light. Alternatively, it may be an amplitude mask in which the individual features modify the amplitude of transmission of the locally transmitted light.

It should be understood that the photomask may additionally contain other first periodic patterns that are employed for printing corresponding other second periodic patterns into the photosensitive layer on the substrate, and that these other first periodic patterns are not necessarily the same as the first periodic pattern, or indeed necessarily the same as each other, but may have different periods, sizes and/or orientations with respect to either the first periodic pattern or each other.

It should be moreover understood that the periodicity of the first periodic pattern and the resulting second periodic pattern printed into the photosensitive layer need not be exactly periodic but may be quasi-periodic, that is have a period that varies slowly over the pattern area according to the prior art of Displacement Talbot Lithography. Similarly, the linear features of a one-dimensional periodic grating pattern need not be purely linear but may have slow curvature such that over a local area of the grating the lines are essentially linear.

The above paragraphs apply not only to the first aspect of the invention but also to the second, third and fourth aspects described below.

According to a second aspect of the present invention, an apparatus is provided for improving the uniformity of exposure of a first periodic pattern in a photomask by a collimated beam in a photolithographic system that uses the Talbot effect to print a second periodic pattern into a photosensitive layer on a substrate that is in proximity to the photomask, which apparatus comprises:
a) a plate that is composed of a material transparent to the beam and that has parallel opposing surfaces separated by a thickness;
b) means for arranging said plate in the photolithographic system such that the beam illuminates the plate at an initial angle of incidence and the beam transmitted by the plate illuminates the photomask; and
c) means for rotating said plate by at least one angle about at least one axis of rotation during the exposure such that the transmitted beam displaces translationally across the photomask.

Preferably, the area of each surface allows transmission of the complete beam through the plate without any truncation of the beam or scattering of the beam from an edge of the plate.

Advantageously, the arranging means arranges the plate such that the beam illuminates it at an oblique initial angle of incidence and the rotation means rotates the plate about an axis of rotation that is parallel to the direction of the beam.

Advantageously, an anti-reflection coating is deposited on at least one of the two opposing surfaces of the plate to reduce power loss in the transmitted beam, for the purpose of reducing the time required for the photolithographic exposure.

Preferably, the beam is monochromatic and the distance between the photomask and a photoresist-coated substrate, which is arranged in proximity to the photomask, is varied during the exposure according to the method of Displacement Talbot Lithography.

The beam alternatively has a desired spectral bandwidth, and a photoresist-coated substrate is arranged at a minimum distance from the photomask according to the method of Achromatic Talbot Lithography.

According to a third aspect of the present invention, a method is provided for improving the uniformity of exposure of a first periodic pattern in a photomask by a collimated beam of monochromatic light in a photolithographic system that prints a second periodic pattern into a photosensitive layer on a substrate that is in proximity to the photomask, which method comprises:
a) providing a plate that is composed of a material transparent to the beam and that has parallel opposing surfaces separated by a thickness;
b) arranging said plate in the photolithographic system such that the beam illuminates the plate at an initial angle of incidence and the beam transmitted by the plate illuminates the photomask; and
c) rotating said plate by at least one angle about at least one axis of rotation during the exposure such that the transmitted beam displaces translationally across the photomask.

Preferably, the beam illuminates the mask at normal incidence and the photolithographic system uses the Talbot effect to print the second periodic pattern from the 1st periodic pattern in the mask. Alternatively, the beam illuminates the mask at an oblique angle that is selected in relation to the period of the pattern in the mask and the wavelength of the monochromatic illumination such that only the 0th and 1st diffraction orders propagate after the photomask according to the method of near-field holography.

According to a fourth aspect of the present invention, an apparatus is provided for improving the uniformity of exposure of a first periodic pattern in a photomask by a collimated beam of monochromatic light in a photolithographic system that prints a second periodic pattern into a photosensitive layer on a substrate that is in proximity to the photomask, which method comprises:
a) a plate that is composed of a material transparent to the beam and that has parallel opposing surfaces separated by a thickness;
b) means for arranging said plate in the photolithographic system such that the beam illuminates the plate at an initial angle of incidence and the beam transmitted by the plate illuminates the photomask; and
c) means for rotating said plate by at least one angle about at least one axis of rotation during the exposure such that the transmitted beam displaces translationally across the photomask.

It should be understood that for all of the above aspects of the present invention, the wavelength of the monochromatic light may be in any part of the spectrum including near-UV, deep-UV and extreme-UV and does not only refer to visible wavelengths.

It should also be understood that the methods and apparatus disclosed here are applicable to lithography systems that require illumination of a mask surface with a collimated beam of light also in cases where the pattern on the mask or the pattern to be printed on the substrate are not periodic in nature.

For all the above aspects of the invention above, it should be understood that the photosensitive layer on the substrate does not necessarily refer to a photosensitive layer that is disposed directly on the surface of the substrate, but may refer instead to a photosensitive layer that is disposed indirectly on the substrate with at least one intermediate layer of another material, such as a metal or a dielectric, between the substrate and the photosensitive layer; or May refer to a photosensitive layer that has been deposited or coated over a pattern or structure formed of the same material as the substrate or at least one other material on the substrate surface that has been previously printed and/or otherwise processed.

The substrate material is not limited and may be, for example, a glass, silicon or other semiconductor material.

These and other aspects of the present invention will now be further described, by way of example only, with reference to the accompanying figures in which:

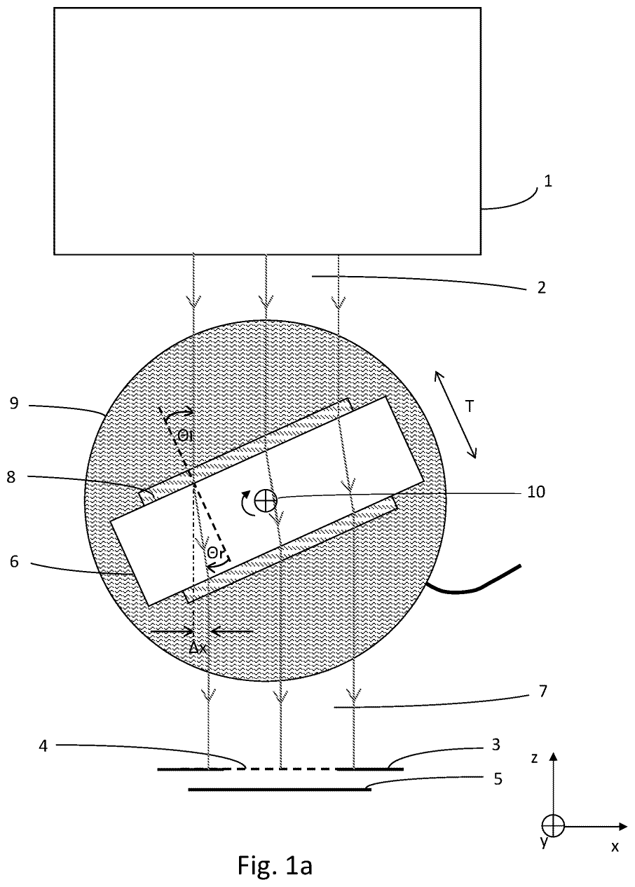

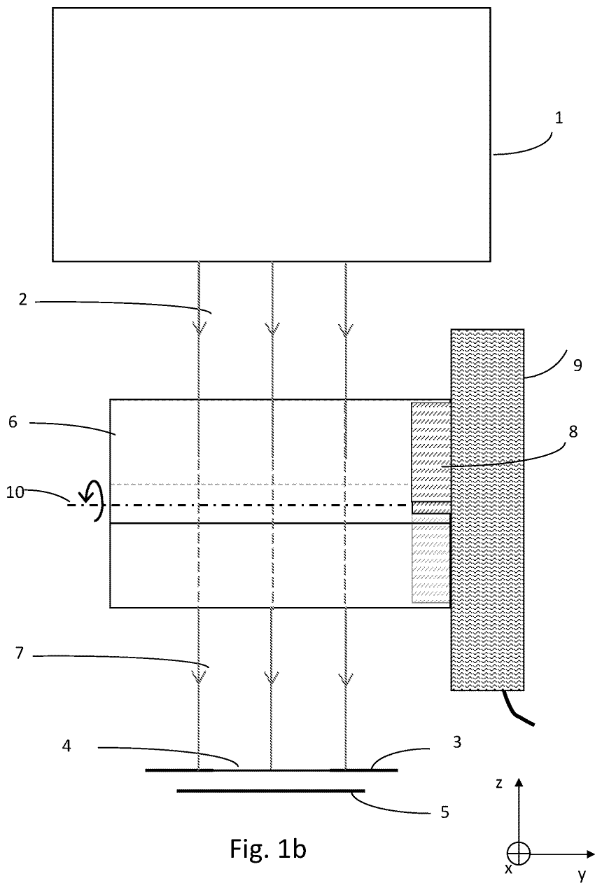

FIG. 1a illustrates a front-side view of a first embodiment of the invention.

FIG. 1b illustrates a right-side view of a first embodiment of the invention.

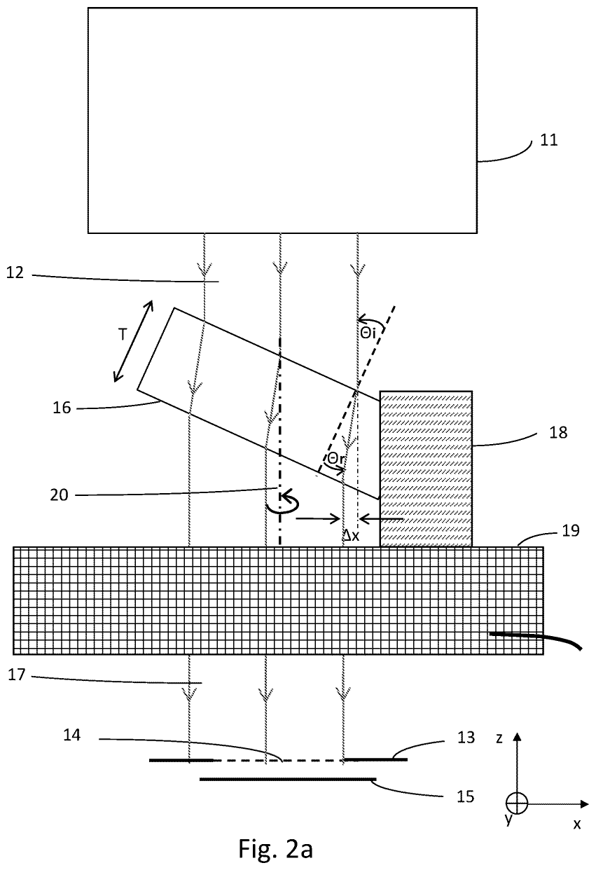

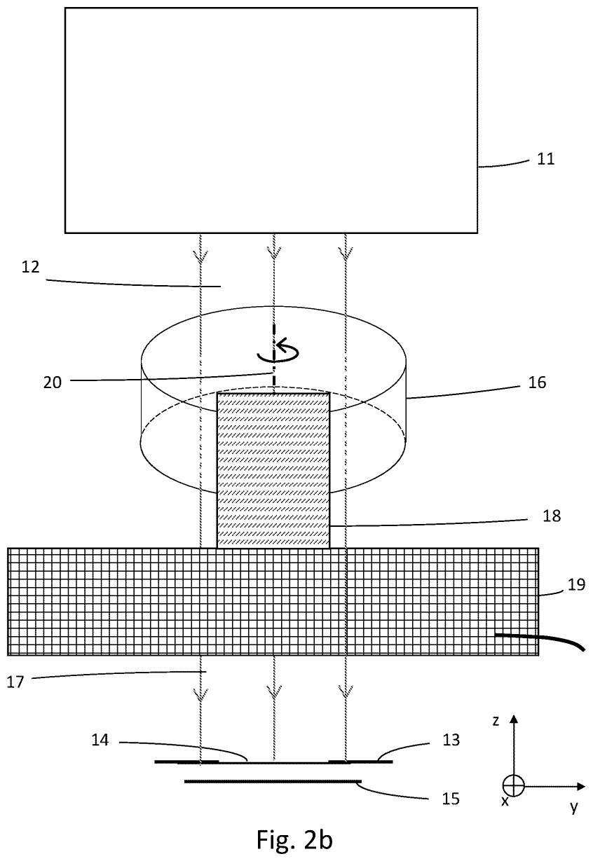

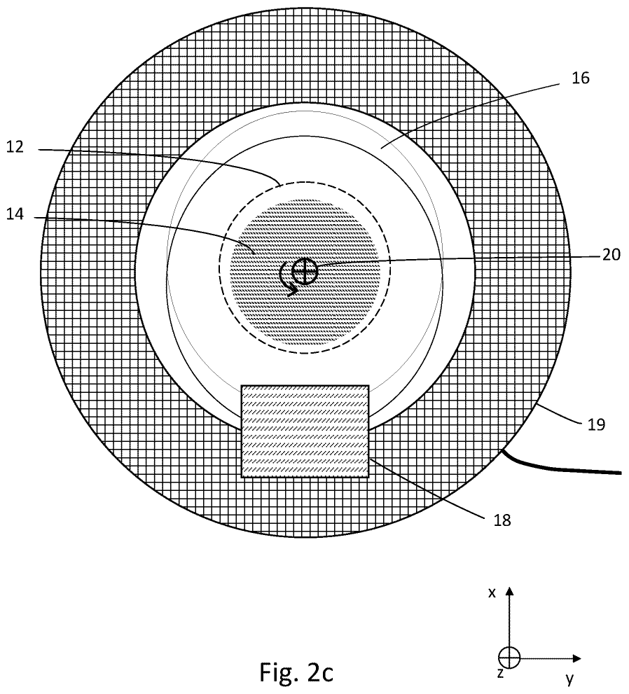

FIG. 2a illustrates a front-side view of a second embodiment of the invention.

FIG. 2b illustrates a right-side view of a second embodiment of the invention.

FIG. 2c illustrates a top-side view of a second embodiment of the invention excluding the illumination module to facilitate clarity

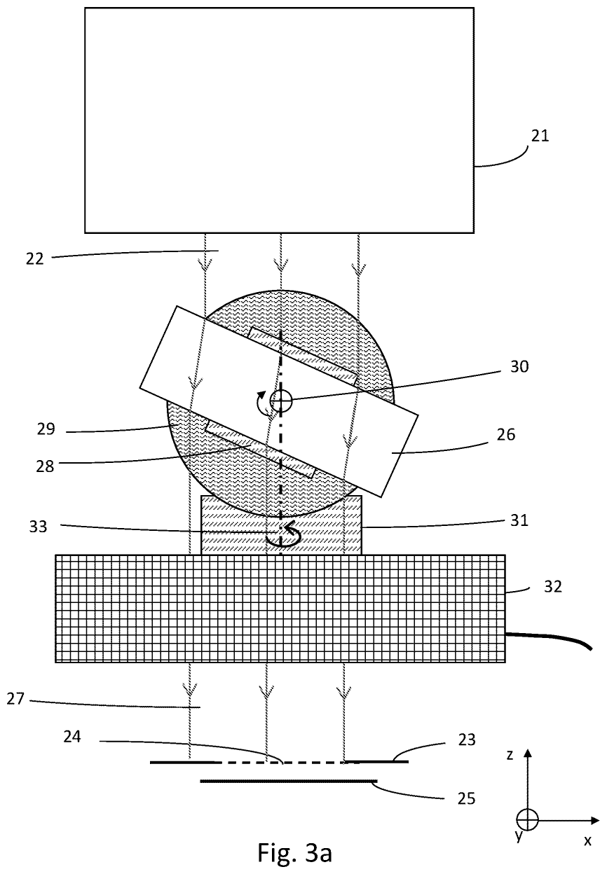

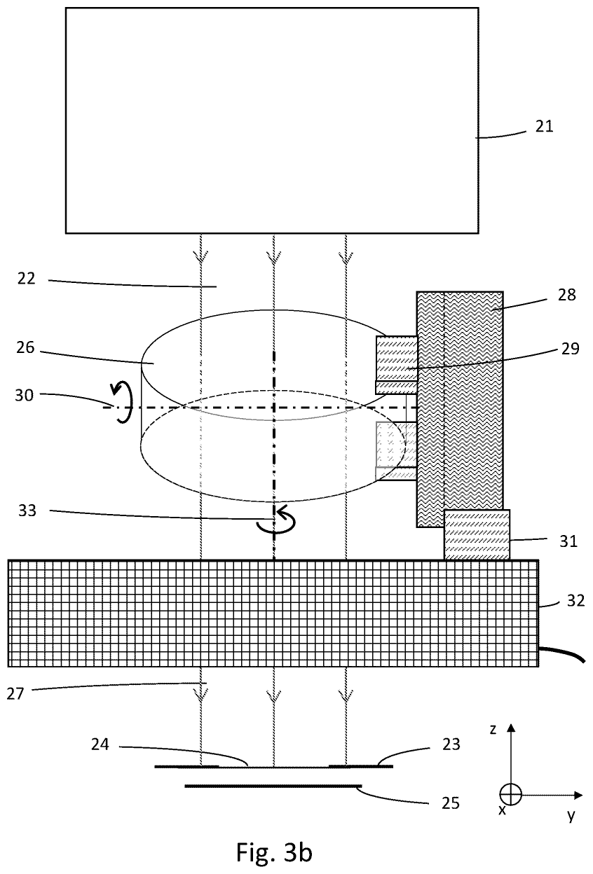

FIG. 3a illustrates a front-side view of a third embodiment of the invention.

FIG. 3b illustrates a right-side view of a third embodiment of the invention.

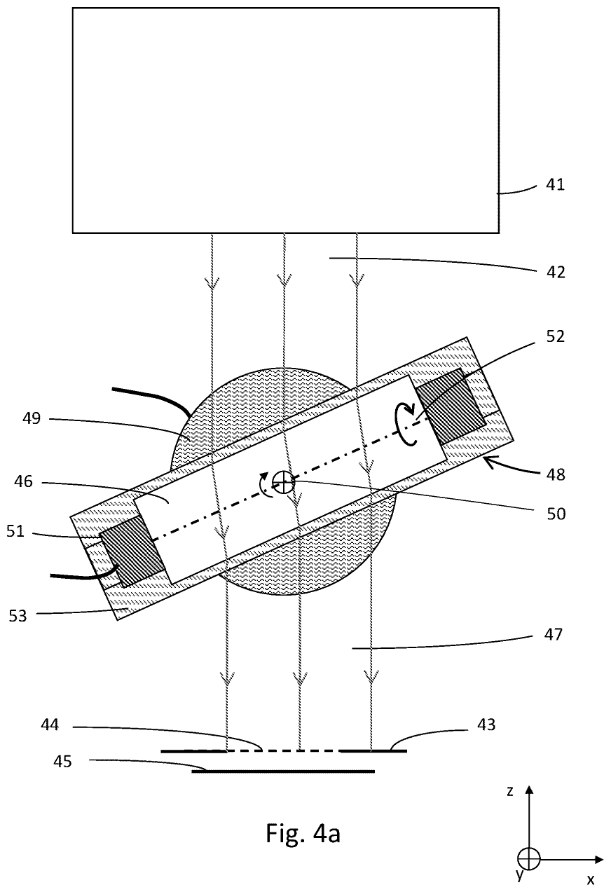

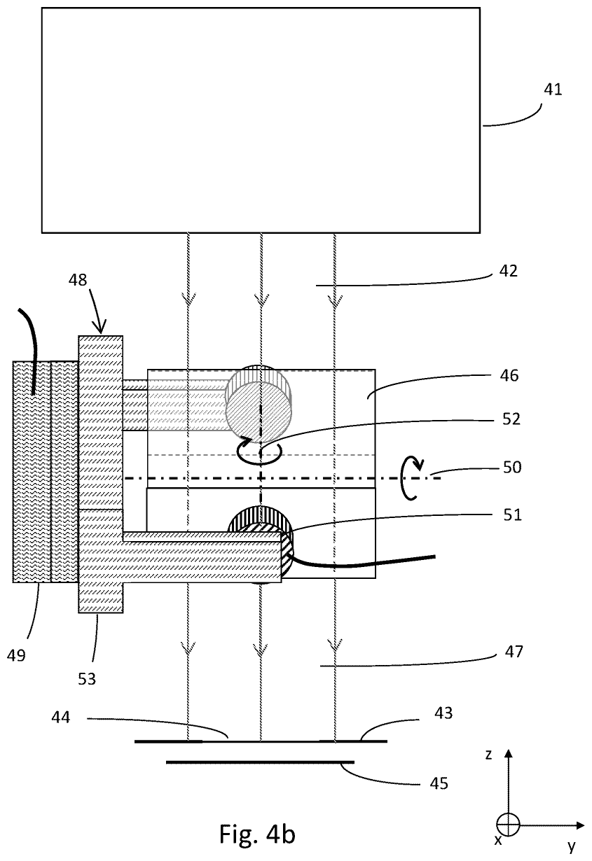

FIG. 4a illustrates a front-side view of a fourth embodiment of the invention.

FIG. 4b illustrates a left-side view of a fourth embodiment of the invention.

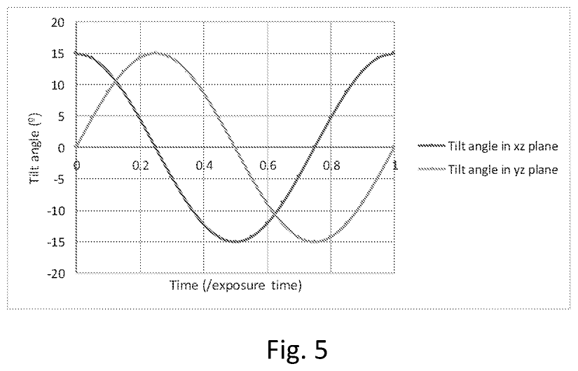

FIG. 5 illustrates time-dependencies of the components of the angle of incidence of the beam on the plate in respectively the xz and yz planes during the exposure.

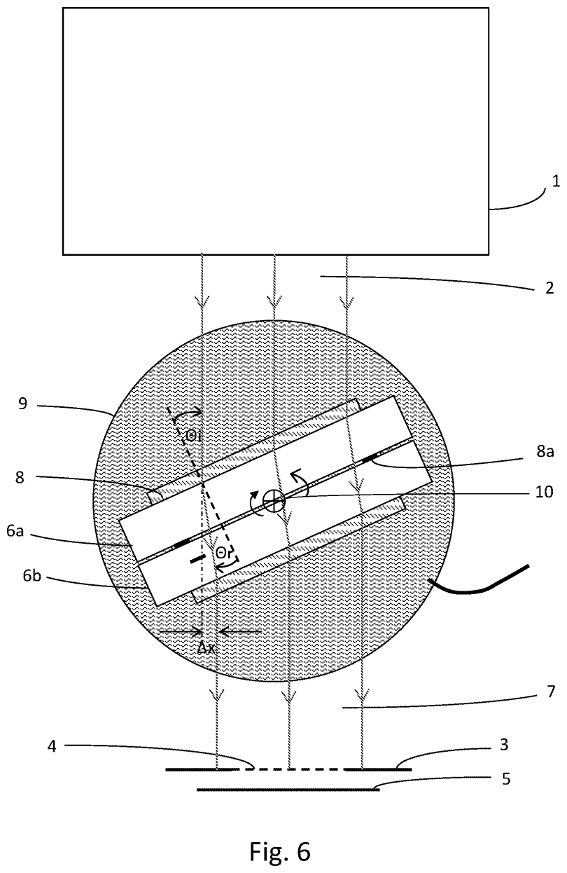

FIG. 6 illustrates a front-side view of a fifth embodiment of the invention

With reference to FIGS. 1a and 1b, which illustrate respectively front and right-side views of a first embodiment of the invention, the illumination module of a photolithographic system, 1, designed for performing Displacement Talbot Lithography projects a beam of collimated monochromatic light, 2, that has a substantially uniform intensity over its circular cross-section. The illumination source, beam-shaping and beam-homogenising optics within the module 1 (not shown) are as described in, for example, U.S. Pat. No. 8,525,973. The beam 2 has a diameter just greater than 4″ and a wavelength of 363.8 nm, so that it is suitable for printing a pattern onto a 4″-diameter substrate or wafer that is coated with standard, i-line-sensitive photoresist. The beam 2 is directed towards a photomask 3 bearing a periodic pattern of features 4 that is positioned above and in proximity to a photoresist-coated wafer 5. Both photomask 3 and wafer 5 are mounted to vacuum chucks (not shown) in the DTL photolithographic system and arranged using standard adjustment means and procedures so that they are mutually parallel and perpendicular to the direction of the illumination beam 2.

Although the beam 2 has a good uniformity of intensity on a macroscale, small imperfections in and on the lenses, such as micro-bubbles within the lenses and micro-digs and dust particles on the lenses' surfaces, produce local inhomogeneities of intensity in the form of spots of lower intensity whose diameter is typically 1-2 mm and whose contrast is up to 5%. Performing a DTL-exposure with such a beam produces, for certain applications, undesirable inhomogeneities in the periodic pattern printed in the photoresist; specifically, lines or features whose size is unacceptably smaller of larger or smaller than the lines or features of the surrounding pattern.

Between the illumination module 1 and the photomask 3 is interposed, according to the present invention, a rectangular plate 6 composed of fused silica through which the beam 2 passes. The plate 6 is shown tilted at an angle with respect to the x axis so that the beam 2 illuminates it at an oblique angle of incidence in the xz plane and perpendicular to the beam in the yz plane. The length and width of the plate 6 are sufficient to enable the complete beam 2 to pass through it unobstructed when the angle of incidence of the beam 2 on the plate 6 is 20° in the xz plane and perpendicular in the yz plane. The plate's thickness is 25 mm. The upper and lower surfaces of the plate 6 have been polished to provide a good flatness of λ/4 and a good scratch/dig quality of 40/20 in order that the collimation and intensity uniformity of the transmitted beam 7 are substantially unaffected by the presence of the plate 6.

The upper and lower surfaces of the plate 6 have furthermore been polished so that they are sufficiently parallel in order that the angle of incidence of the transmitted beam 7 on the photomask 3 remains sufficiently constant when the plate 6 is rotated about the range of angles employed in this embodiment. In the same way that too large a range of angles of incidence in the beam instantaneously illuminating each point of the mask (i.e. poor collimation) can cause unacceptable smearing, or blurring, of the features of the periodic pattern printed into the photosensitive layer, so too can too large a time-varying angle of incidence of the beam on the mask during exposure, caused by too large a wedge angle between the upper and lower surfaces of the substrate, result in unacceptable blurring of the features of the periodic pattern printed on the wafer. For a mask-to-wafer separation of d, a change in angle of incidence of Δϕ of the illuminating beam causes the intensity distribution illuminating the photoresist to laterally displace by a distance ˜dΔϕ. It is therefore preferable that this distance is less than 1/10 of the period of the printed pattern, and most preferably less than 1/20 of the period. For example, if the period of the printed pattern is 250 nm and the mask-to-wafer separation is 0.1 mm, then it is most preferable that that angle of incidence of the beam on the photomask remains constant to <0.12 mR during the exposure. The degree of parallelism consequently required between the plate surfaces may be readily determined using Snell's law by a person skilled in basic optics. If the plate is rotated during exposure so that the angle of incidence of the beam on the plate varies over the range −θ₁ to θ₁ and the residual wedge angle between the parallel surfaces is ω, then it can be derived that the angle of incidence of the beam, φ, on the photomask varies by

$$Δφ = ( \frac{cos {θ}_{r}}{cos {θ}_{1}} - 1 ) n ω , \qquad equ . ( 1 )$$

where θᵣ is the angle of refraction of the beam within the plate when the angle of incidence is θ₁, and n is the refractive index of fused silica at the illumination wavelength.

Evaluating this with θ=20°, n=1.47 and ω=3 arcmin yields Δω=0.05 mR, which would produce negligible blurring of a printed pattern with period 250 nm. Such parallelism can be readily achieved by manufacturers of standard optical parts.

The upper and lower surfaces of the plate 6 are anti-reflection coated to minimize power loss in the beam and exposure time.

The plate 6 is attached by fixation brackets 8 to a motorized rotation stage 9 that allows the plate 6 to be rotated about a rotation axis 10 that is parallel to the y axis. The plate 6 does not need to be rotated with high speed or high angular resolution (1°/s and 0.1° are respectively sufficient), so a suitable stage is readily obtainable from many suppliers such as Newport Corporation, Irvine, U.S. (www.newport.com). The plate 6 is shown inclined at an angle to the horizontal so that the beam 2 illuminates the plate 6 at an oblique angle of incidence θᵢ. Refraction of the beam 2 as it passes through the plate 6 produces a transmitted beam 7 that is parallel to the incident beam 2 but laterally offset from it by a distance, Δx (indicated in FIG. 1), given by

$$Δ x = \frac{T sin ( {θ}_{i} - {θ}_{r} )}{cos {θ}_{r}} , \qquad equ . ( 2 )$$

where T is the thickness of the plate and θᵣ is the angle of refraction of the beam within the plate and ni is the refractive index of fused silica at the illumination wavelength.

For small values of θᵢ, the dependence of the lateral offset on angle of incidence approximates to a linear relationship given by

$$Δ x = T {θ}_{i} ( n - 1 ) / n , \qquad equ . ( 3 )$$

Thus, rotating the plate 6 with constant angular speed over a range of small angles of incidence (e.g. ±20°) causes the transmitted beam 7 to scan with substantially constant speed across the photomask 3.

The stage 9 initially orientates the plate 6 so that at the start of the exposure the initial angle of incidence of the beam 2 on the plate 6 is selected to be −20°. During the exposure, the stage 9 then rotates the plate 6 by an angle of 40° using a constant speed of rotation so that the angle of incidence of the beam 2 on the plate 6 reaches +20° at the end of the exposure. The exposure time required for printing the desired pattern on the wafer is 40 seconds, so the rotation speed selected is 1°/s. This rotation of the stage 9 during the exposure produces a slow displacement, or scan, of the transmitted beam 7 across the photomask 3. Using equ. (2), the scan distance is calculated from the rotation angle (−20° to +20°), the plate thickness (25 mm) and plate's refractive index (n=1.47) to be ˜5.9 mm. This scanning of the transmitted beam 7 during the exposure therefore blurs, or smears, the inhomogeneities in the time-integrated intensity distribution illuminating the photomask 3. The reduction in contrast of the inhomogeneities may be estimated as follows: the displacement of a ˜2 mm size defect over a distance ˜5.9 mm produces a smear region of length ˜6.9 mm, so the contrast of the defect is reduced by a factor of ˜6.9/2≈3.5. Thus, a defect with a contrast of 10% in the instantaneous beam would have a contrast ˜3% in the time-integrated distribution, which satisfies most applications.

It should be noted that the lateral displacement of the beam 7 in the x direction during the exposure introduces some non-uniformity at the edges (in the ±x directions) of the time-integrated intensity distribution illuminating the photomask; specifically, the exposure energy density at the edges of the beam taper off over a distance of the lateral displacement concerned, so over ˜5.9 mm, thereby reducing, by the same value, the width of the uniform region of the time-integrated distribution. The width, in the x direction, of the pattern 4 in the photomask 3 then needs to be smaller than the width of this region for it to be printed uniformly onto the wafer 5.

Whereas the speed of rotation of the stage 9 is preferably selected so that it reaches the desired final angle at the end of the exposure, in other embodiments it may be selected so that the stage 9 reaches the final angle at some time before the end of the exposure or, equivalently, starts its rotation at some time after the start of the exposure and reaches its final angle at the end of the exposure. Such non-optimized selection of the rotation speed generally results, however, in a non-uniform smearing of the defect, so produces a higher contrast at an end of the smear region than would be obtained using an optimized speed of rotation, which is usually undesirable.

In the embodiment described above the plate 6 is initially arranged to be static at the start of the exposure and tilted at an angle such that the beam 2 initially illuminates it at the desired initial angle of incidence. In a variant of this embodiment the plate 6 is initially arranged at another angle of tilt and then, before the exposure, rotated with a selected speed so that at the start of the exposure the beam 2 initially illuminates the plate at the desired initial angle of incidence. The plate 6 then continues to rotate with the same, or a different, speed during the exposure to produce the required displacement of the transmitted beam at the photomask 3.

In another variant, the plate 6 is repetitively scanned over the range of angles described in the first embodiment before the exposure starts, so that when the exposure starts the initial angle of incidence of the beam on the plate is some arbitrary angle over the desired range of angles. The plate 6 then continues to repetitively scan over the same range of angles during the exposure, preferably with an optimized speed of scan and negligible delay between successive scans, so that by the end of exposure it has preferably completed an integral number of cycles of the range of angles, thereby minimizing the contrast of the smeared feature in the time-integrated distribution illuminating the photomask 3.

Whereas the rotation of the plate 6 by the selected angle of rotation is preferably achieved using a constant speed of rotation, so as to achieve a uniform smearing of the defect over the smear region, it may alternatively be achieved using a variable speed of rotation. Such a variable-speed strategy generally results, however, in a non-uniform smearing of the defect, so produces a locally higher contrast of inhomogeneity (compared to that produced with a constant speed) somewhere along the smear region, which is usually undesirable.

Using the apparatus of this embodiment, a smaller or larger factor of contrast reduction in the smeared defect may be obtained by scanning the plate 6 over respectively a smaller or larger range of angles so that the defect scans across the photomask 3 by a smaller or larger distance. The range of angles should preferably not be so large that either the AR-coatings on the plates' surfaces cease to function well or that the exposure beam 2 is truncated by an edge of the plate 6.

Although the angular scan of the plate 6 described in this embodiment is symmetric about normal incidence, in other variants of this embodiment the plate 6 may be scanned asymmetrically so that the angle of incidence of the beam on the plate varies, for example, between −15° and 25°, or between 0° and 30°.

Further, whereas the angular scan of the plate 6 described above is a single scan, the same apparatus may be used to perform a double-scan of the plate 6 during the exposure; that is, the plate 6 may be rotated so that the angle of incidence of the beam on the plate 6 is scanned from −20° to +20° in the 1^{st} half of the exposure and then scanned back again from +20° to −20° in the 2^{nd} half of the exposure. For this embodiment the speed of scan should be substantially constant during each of the forward-direction and backward-direction scans (but not necessarily the same for both 2 directions), and the time for switching scan-direction between the forward- and backward-scans should preferably be negligible in relation to the total exposure time. Clearly, such a double-scan variant of the first embodiment may be extended to other, multiple-scan variants. For multiple scans, it is less important that the final scan is completed exactly at the end of the exposure because the accumulated exposure dose from the earlier scans ensures a higher level of uniformity over the smear region.

Rather than angularly displacing the plate 6 over the desired, or selected, angle of rotation with a constant speed of scan, the apparatus of the first embodiment may achieve the same angular displacement using instead a stepping motion of the stage 9 that approximates to a displacement at constant speed. For example, the stage 9 may be rotated in small angular steps of 0.5° from −20° to +20°, with a constant step frequency and a short dwell time between steps. This would also achieve a good uniformity over the smeared-out feature.

Whereas the rotation axis 10 of the stage 9 employed in the first embodiment is arranged parallel to the y axis and consequently exactly orthogonal to the direction of the beam 2, this is not essential. For maximizing the displacement of the beam at the photomask 3 produced by a particular angle of rotation of the plate about its axis of rotation it is though preferable that the rotation axis 10 is substantially orthogonal to the direction of the beam: preferably, it should be orthogonal to within ±20° and most preferably orthogonal to within ±10°.

In the first and other embodiments, it is preferable that the speed of variation of the gap between photomask and photoresist-coated wafer that is employed for the DTL exposure is selected in relation to the speed of the rotation of the plate about the at least one axis of rotation such that either 2 or more scans of the gap variation occur during the or each rotational scan of the plate or conversely that 2 or more rotational scans of the plate occur during the or each scan of the gap variation. By desynchronizing the DTL scan with respect to the rotational scan of the plate in such a manner, the uniformity of the DTL printed pattern is further optimized in the regions of the local inhomogeneities in the intensity distribution illuminating the photomask.

With reference to FIGS. 2a, 2b and 2c, which illustrate a second embodiment of the invention, a beam 12 from the illumination module of a lithographic system 11 designed for printing periodic patterns using the technique of DTL is directed towards a photomask 13. The photomask 13 defines a periodic pattern of features 14 and is positioned above and in proximity to a photoresist-coated wafer 15. Between the illumination module 11 and the photomask 13 is located a circular, 25 mm-thick plate 16 formed of fused silica that is inclined at an angle so that the beam 12 illuminates it at an initial angle of incidence of 15°. The diameter of the plate 16 is sufficient to allow the complete beam 12 to pass though it unobstructed at this angle of incidence. The upper and lower surfaces of the plate 16 have been polished to similar flatness and scratch/dig quality as the plate 6 in the first embodiment.

The plate 16 is mounted by a fixation part 18 to a rotation stage 19 whose axis of rotation 20 is parallel to the direction of the exposure beam 12 and approximately centered on the beam 12. Unlike the stage 9 employed in first embodiment, the stage 19 has an open aperture centered on its rotation axis 20 that allows the beam 17 transmitted by the plate 16 to pass unobstructed through the stage 19 and illuminate the photomask 13. The passage of the beam through the aperture of the rotation stage 19 can be clearly seen in the top-side view of the apparatus of the second embodiment shown in FIG. 2c. The illumination module 11 is omitted from this FIG. for clarity's sake.

The upper and lower surfaces of the plate 16 have been polished to provide good parallelism between the two so that when the tilted plate 16 is rotated about the rotation axis 20 by the stage 19, the angle of incidence of the transmitted beam 17 remains substantially constant at the photomask 13. The parallelism needed can be readily determined by a person skilled in basic optics using Snell's law. A residual wedge angle, w, between the upper and lower surfaces results in a variation of the angle of incidence of the beam at the photomask of ˜ω as the plate rotates. A residual wedge angle of 20 arcsec therefore ensures that the angle of incidence of the transmitted beam 17 at the photomask 13 remains constant to ˜0.1 mR, which is sufficient for printing a 0.5 μm-period pattern if the distance between the photomask 13 and wafer 15 of 0.1 mm. The upper and lower surfaces of the plate 16 are anti-reflection coated to substantially maximise the intensity of the transmitted beam 17.

As in the first embodiment, the stage 19 does not need to rotate with a high rotation speed or high angular resolution, so can be obtained from many suppliers, such as from Newport Corporation, for example, one of its range of DC Motor Rotation Stages. As in the first embodiment, the oblique angle of incidence of the beam 12 on the plate 16 and the refraction of the beam as it passes through the plate 16 produces a lateral offset of the transmitted beam 17 with respect to the incident beam 12. Using the apparatus of this embodiment, however, the tilt angle of the plate 16 with respect to the rotating platform of the stage 19 is fixed and the axis of rotation of the stage is parallel to the direction of the beam, which causes the magnitude of the angle of incidence of the beam on the plate to remain constant as the stage rotates, thus resulting in a constant magnitude of lateral offset of the transmitted beam. The plane of incidence of the beam on the plate 16, however, rotates with the stage and so the direction of the lateral offset similarly rotates about the axis 20, thereby producing a circular scan trajectory of the beam 17 at the photomask 13. A localized inhomogeneity of intensity in the transmitted beam 17 is therefore blurred, or smeared, over an annular region in the time-integrated intensity distribution exposing the photomask 13.

The stage 19 is initially stationary and, when the exposure starts, is rotated with a constant speed that is selected to be 6°/s so that the stage 19 completes a single full rotation of 360° at the end of the required exposure time of 60 s. The single rotation of the stage 19 during the exposure ensures that an intensity inhomogeneity in the instantaneous beam 17 illuminating the photomask 13 is uniformly smeared over an annular region in the time-integrated intensity distribution illuminating the photomask 13. The mean radius of the annular region is the lateral offset distance of the transmitted beam 17 with respect to the incident beam 12 that is produced by the tilted plate 16; so is calculated using equ. (2) and the values concerned (θᵢ=15°, plate thickness 25 mm and n=1.47) to be 2.15 mm. The circumference of this annular region at the mean radius is therefore ˜13.5 mm. The reduction in contrast of a defect of a certain size can be estimated: a 1 mm-size defect is smeared over a region of (annular) length 13.5 mm, so its contrast is reduced by a factor of ˜13.5; thus, a defect with ˜10% contrast in the instantaneous beam 17 is reduced to one with contrast <1% in the time-integrated distribution illuminating the photomask 13, which is negligible for most applications.

Whereas the speed of rotation in this embodiment is preferably selected so that a single rotation of the stage 19 occurs during the exposure, the rotation speed may be alternatively selected so that a larger whole number of rotations occurs (i.e. rotation angles of 720°, 1080°, etc), which produces the same result of a uniform smearing of the defect over the annular region concerned. A rotation speed that produces a non-whole number of rotations, and preferably larger than half a rotation, i.e. larger than 180°, may alternatively be used but with the disadvantage that the inhomogeneity is not uniformly smeared over the annular region, which results in a value of contrast somewhere over the annular that is higher than it would otherwise be. The difference between the optimized and non-optimized values of contrast produced by respectively the whole number and non-whole number rotations of the stage reduces with increasing number of rotations so can be made negligible by arranging the speed so that, for example, at least 2 rotations occur during the exposure.

Whereas the starting and stopping of the stage's rotation described in the embodiment above are synchronized with the beginning and end of the exposure, this is unnecessary. What is important is that the preferably whole number, of rotations is performed during the exposure time. The stage's rotation may therefore be activated before the start of the exposure and/or switched off after the end of the exposure. The speed of rotation, though, should still preferably be calculated from the exposure time so that a desired whole number of rotations is completed during the exposure. A different or non-optimized speed may alternatively be used but with the above-mentioned disadvantage that the inhomogeneity is not uniformly smeared over the annular region.

As for the first embodiment, the rotation stage 19 may alternatively be rotated with a variable speed, but this would generally lead to higher than otherwise contrast somewhere in the smear region, so could be undesirable.

Similarly equivalent to the first embodiment, the rotation stage 19 may alternatively be displaced over the desired angle of rotation using a sequence of incremental steps rather than using a constant or variable speed. For example, it may be angularly displaced over 360° using 18 incremental steps of 20° with a constant step frequency and constant dwell time between steps. For short exposure times of <60 s, however, this would not be an optimal choice because it would require high acceleration and decelerations of the stage 19 for each step which could generate undesirable vibrations between the photomask and the wafer, so may degrade the quality of the periodic pattern printed on the wafer 15.

Whereas the rotation axis of the stage employed in the second embodiment is arranged parallel to the direction of the beam, which is preferred, in a variant of this embodiment the rotation axis is alternatively arranged so that it is tilted at 5° with respect to the direction of the beam. Such as asymmetric arrangement produces a variation of the magnitude of the angle of incidence of the beam on the plate as the plate is rotated about its axis, and so produces a slightly elliptical rather than circular scan trajectory of the beam illuminating the photomask and a slight variation in the contrast of the time-integrated intensity distribution of each defect around the elliptical region. The results obtained are, however, substantially the same as produced with the circular scan trajectory of the second embodiment. For minimizing the contrast of the time-integrated intensity distribution over the smear region for a particular tilt angle of the plate (with respect to the axis about which it is rotated during the exposure) and plate thickness, it is though preferable that the rotation axis of the stage is aligned substantially parallel to the direction of the beam; in particular, that it is aligned preferably to within ±10° of the beam direction and most preferably to within ±5°.

In a third embodiment of the invention, with reference to FIGS. 3a and 3b, an illumination module 21 of a DTL-based photolithography system emits a beam 22 of collimated and monochromatic light at a near-UV wavelength. The beam 22 is directed towards a mask 23 defining a periodic pattern 24 that is located above and in proximity to a photoresist-coated wafer 25. Between the illumination module 21 and the mask 23 is a 15 mm-thick plate 26 formed of fused silica whose upper and lower surfaces are parallel and anti-reflection coated for the wavelength concerned. The requirement on the parallelism of the surfaces may be determined as in the second embodiment. The plate 26 is inclined at an oblique angle to the beam 22 and its dimensions are such that the complete beam 22 passes through it without truncation. The plate 22 is attached by fixation parts 28 to the platform of a first motorized rotation stage 29 whose rotation axis 30 is orthogonal to the direction of the beam 22. The base of the rotation stage 29 is attached by a bracket 31 to the platform of a second motorized rotation stage 32 whose rotation axis 33 is parallel to the direction of the beam 22 and approximately centered on the beam 22 at the output plane of the illumination module 21. This second stage 32 has a central through-aperture that is centered on the stage's rotation axis 33 and is large enough to enable the beam 27 transmitted by the plate 26 to pass unobstructed through the stage 32 when it rotates.

As in the first and second embodiments, refraction of the beam 22 as it passes through the tilted plate 26 produces a transversal offset of the transmitted beam 27 with respect to the incident beam 22 whose magnitude is given by equ. (2) and whose direction of offset is parallel to the plane of incidence of the beam 22 on the plate 26. An angular displacement of the first rotation stage 29 therefore produces a change in the magnitude of the transversal offset, whereas an angular displacement of the second rotation stage 32 produces a change in the direction of the offset.

As in the previous embodiments, the beam 22 generated by the illumination module 21 has a good uniformity of the intensity at the macroscale but has a number of undesirable inhomogeneities of intensity at the mm-scale: in a few localized regions of radius up to ˜1 mm the intensity deviates by up to ˜10% from that of the surrounding region.

Before the DTL-based photolithographic exposure proceeds, the first rotation stage 29 is adjusted in order that beam 22 illuminates the plate 26 at an initial angle of incidence of 10°. At the start of the exposure, the second rotation stage 32 is activated to rotate the plate 26 about the axis 30 with a constant speed of 18°/s, the speed being selected so that the stage 32 completes 2 full rotations during the desired exposure time of 40 seconds. At about halfway through the exposure, i.e. after ˜20s, the first rotation stage 29 adjusts the tilt angle of the plate by 13° in a time <1 s (that is short compared to the duration of the exposure) so that the angle of incidence of the beam 22 on the plate is 23° during essentially the second half of the exposure. The magnitude of the adjustment to the tilt angle is preferably selected so that the transversal offset of the transmitted beam 27 is enlarged by at least the largest size of the intensity inhomogeneities, which minimizes the contrast of the resultant inhomogeneities in the time-integrated intensity distribution illuminating the photomask 23. Changing the tilt angle of the 25 mm-thick fused silica plate 26, whose refractive index is ˜1.47, from 10° to 23° enlarges the transversal offset from 1.5 mm to 3.6 mm (using equ. 2), i.e. by 2.1 mm, so by a distance that is at least as large as the 2 mm largest size of the inhomogeneities.

The rotation of the second stage 32 in each of the first half and second half of the exposure produces a circular scanning motion of each inhomogeneity at the plane of the photomask 23. The radius of the scanning trajectory in each half-exposure corresponds to the transversal offset of the transmitted beam 27 produced by the respective tilt angle of the plate 26. By arranging that the transversal offset is enlarged by the largest size of inhomogeneity between the first half and second half of the exposure, the composite region over which each inhomogeneity is scanned during the exposure is substantially annular whose width (difference between inner and outer inner radii) is approximately twice the largest size of inhomogeneity. The total length of scan path of each homogeneity during the exposure is the sum of the circular trajectories produced by the two half exposures, so is 2π×(1.5 mm+3.6 mm)≈32 mm. The area scanned by each (largest) inhomogeneity is therefore 32 mm×2 mm=64 mm². Since the area occupied by each of the (largest) inhomogeneities in the instantaneous beam is ˜3.1 mm², it is estimated that the contrast of the inhomogeneity is reduced by a factor of ˜64/3.1≈20.6. Thus, an inhomogeneity with a contrast of 10% in the instantaneous distribution will be reduced to one with ˜0.5% contrast in the time-integrated distribution, which is negligible for most applications.

The contrast reduction factor estimated above, though, is a mean value over the annular region: since the radius of the trajectory scanned by each inhomogeneity in the first half exposure is ˜40% of that scanned in the second half exposure, the contrast reduction factor obtained over the region scanned in the first half exposure is ˜40% of that obtained over the region scanned in the second half exposure. The mean value calculated above may be more uniformly obtained over the complete annular region by using exposure times for the first and second parts of the exposure that are instead proportional to the respective transversal offsets of the transmitted beam (while ensuring that the total exposure time corresponds to the desired value of 40 s); so, exposure times of ˜12 s and ˜28 s respectively for the first and second parts of the exposure would achieve the desired effect. Of course, the rotation speeds of the second stage 32 during the first and second parts of the exposure need to be selected accordingly so that a single full rotation is preferably performed during each of the parts.

Using the apparatus of the third embodiment, many variants of the above-described procedure may be alternatively employed for suppressing localized inhomogeneities in the exposure beam. For example, the exposure may instead be divided into 3 or more parts, rather than just two, using a different tilt angle of the plate 26 for each part, and extrapolating the same methodology as described above. In another variant, rather than continuing to expose the photomask 23 during the short period of time that the first rotation stage 29 adjusts the tilt angle of the plate 26 between the first half and second half of the exposure, the exposure beam 22 may be alternatively switched off during this period and switched on again after the tilt angle has been adjusted. The magnitude of contrast reduction obtained would be substantially the same. In yet another variant, rather than the first rotation stage 29 being adjusted in a short period of time substantially between the two (or more) parts of the exposure as described in the third embodiment above, the stage 29 may, alternatively, be rotated continuously and simultaneously with the rotation of the second stage 32, and preferably with a rotation speed that is selected such that the change of angle of the first stage after a full rotation of the second stage 32 corresponds to that recommended in the third embodiment, i.e., so that the transversal offset of the transmitted beam is enlarged by at least the largest size of the intensity inhomogeneities. By rotating the two stages 29, 32 simultaneously in the manner described each of the localized inhomogeneities in the exposure beam is scanned in a spiral trajectory over the photomask 23, with the distance between successive loops of the spiral corresponding to the largest size of inhomogeneity.

As for the earlier embodiments, the plate may be arranged so that it is static at the start of the exposure and such that the beam initially illuminates it at an initial angle of incidence. In a variant of the embodiment it may be arranged that one or both of the stages is, or are, rotating about their respective axes before the exposure such that at the start of the exposure the beam illuminates the plate at a desired initial angle of incidence or at an initial angle of incidence that is within a desired range of angles of incidence, after which the stages rotate sequentially and/or simultaneously during the exposure to produce the desired displacement of the beam across the photomask.

Whereas the change of tilt angle of the plate 26 in the third embodiment is obtained using a motorized rotation stage 29, in another variant of this embodiment the rotation of the plate 26 may be obtained by other means, for example arranging that one side of the plate 26 is attached to a hinge and that the opposite side of the plate 26 is displaced using a linear actuator.

The rotation axes of the first and second rotation stages employed in the third embodiment are preferably arranged respectively orthogonal and parallel to the direction of the beam. This, however, as in the earlier embodiments is not essential: in variants of this embodiment, the axes are arranged at oblique angles to the direction of the beam. Such oblique arrangements of the rotation stages produce similar reductions in contrast of time-integrated inhomogeneities illuminating the photomask if the length of the non-scan trajectory of the beam illuminating the photomask is the same as that of the trajectory produced using the third embodiment. The rotation axes of the first and second rotation stages are though preferably arranged so that they are substantially respectively orthogonal and parallel to the direction of the beam (with similar accuracy as specified in the earlier embodiments).

In a fourth embodiment of the invention, with reference to FIGS. 4a and 4b, a ˜10 cm-diameter beam 42 of collimated light at a near-UV wavelength is projected from the illumination module 41 of a DTL-exposure system. The beam 42 is directed, like in the previous embodiments, towards a photomask 43 defining a periodic pattern that is arranged above and in proximity to a photoresist-coated wafer 45 in the DTL system. The beam illuminating the photomask 43 is uniform at the macroscale but has local inhomogeneities of spatial dimension ˜1 mm and contrast ˜10%.

Between the illumination module 41 and the photomask 43 is a 20 mm-thick plate of fused silica 46 through which the complete beam 42 passes. The upper and lower surfaces of the plate are parallel and anti-reflection coated for the wavelength concerned. The requirement on the parallelism of the surfaces may be determined as in the second embodiment. The plate 46 is mounted to a motorized 2-axis gimbal system 48 comprising a first stage 49 for rotating the plate 46 about a first axis 50 that is orthogonal to the direction of the beam 42 (and in the y direction), and a second stage 51 for rotating the plate 46 about a second axis 52 that is orthogonal to the first axis 50. The second stage of the gimbal system is mounted to the first stage, so the orientation of the second axis rotates with the rotation of the first stage, though remains substantially orthogonal to the direction of the beam during the exposure. The plate 46 is mounted by adaptor parts (not shown in the figure) to the second stage 51 which is itself mounted by a yoke 53 to the first stage 49, so a rotation of the first stage 49 produces a rotation of the axis 52 of the second stage 51. Suitable motorized 2-axis gimbal systems are available from, for example, Newmark Systems Inc., California, U.S. (www.newmarksystems.com). As in the previous embodiments, a tilt of the plate 46 with respect to the direction of the incident beam 42 introduces a transversal offset of the transmitted beam 47, so changing the tilt angle of the plate 46 during the exposure produces a translational displacement of the beam 47 across the photomask 43. The tilt of the plate 46 is initially adjusted using the first and second rotation stages 49, 51 so that at the start of the exposure the components of the angle of incidence of the beam 42 in the xz and yz planes on the plate 46 are respectively +15° and 0°. This tilt of the 20 mm-thick plate 46 produces, using equ. (2), +1.7 mm transversal offset of the transmitted beam in the xz plane. When the exposure begins, the control system (not shown) initiates angular scanning motions of the two rotation stages 49, 51 in which the tilt angle of the plate 46 in the xz plane is varied, by the first stage 49, between +15° and −15° with a cosinusoidal time dependence as illustrated in FIG. 5, the tilt angle of the plate 46 in the yz plane is varied, by the second stage 51, between the same angles +15° and −15° but with a sinusoidal time-dependence as illustrated in FIG. 5, and the varying speeds of the angular motions are selected so that each of the stages 49, 51 completes a single oscillation of its motion at the end of the exposure. As a result of these scanning motions in the xz and yz planes, the angle of incidence of the beam 42 on the plate 46 has constant magnitude during the exposure but the plane of incidence of the beam 42 on the plate 46 rotates with a constant speed and completes a single rotation at the end of the exposure. The beam 47 illuminating the photomask 43 is consequently displaced translationally, i.e. with no or negligible change in angle of incidence of the beam, in a single circular trajectory with a radius of 1.7 mm. A localized inhomogeneity of diameter 1 mm is therefore scanned over a region of area 2π×1.7 mm×1 mm=10.7 mm², which is ˜13.6× larger than area of the inhomogeneity, so if the contrast of the original inhomogeneity (in relation to the intensity of the surrounding beam) is ˜10%, then the contrast of the residual inhomogeneity in the time-integrated intensity distribution illuminating the photomask is ˜0.7%, which is negligible for the majority of applications.

The circular scanning motion of the beam 47 on the mask 43 obtained with the 2-axis gimbal system 48 of this fourth embodiment is therefore similar and substantially equivalent to the circular scanning motion obtained with the rotation of a tilted plate about a single axis obtained using the apparatus and procedure of the second embodiment. The apparatus of the second embodiment is, though, mechanically simpler so generally preferred.

The apparatus of the fourth embodiment may be used with a number of alternative angular scanning or stepping schemes of the rotation stages 49, 51 to similarly suppress the contrast of localized inhomogeneities in the exposure beam 42. For example, faster oscillations of the rotation stages 49, 51 may be employed in order that two or a larger whole number of oscillations of the stages occur during the exposure time, whereby the exposure beam 47 is scanned a larger number of times around the circular trajectory during the exposure. Alternatively, faster (or slower) oscillations of the rotation stages 49, 51 may be employed such that a non-integral number of oscillations of the stages occurs during the exposure time, and preferably the non-integral number is >1.

In another alternative variant of this embodiment, the amplitudes of the oscillating tilt angles in the xz and yz planes have different values, so that the scanning trajectory of the transmitted 9 beam 47 illuminating the photomask 43 follows instead an elliptical rather than circular trajectory. In another variant, a number of oscillations of the two rotation stages 49, 51 are employed and the amplitude of the oscillations is gradually increased (or decreased) in time, thereby producing a spiral scanning trajectory of the exposure beam 47 at the photomask 43. In other variants, the motions of the two rotation stages 49, 51 are not oscillations but, for example, a sequence of linear scans that produces, for example, a raster scan trajectory of the beam 47 illuminating the photomask 43, or a trajectory around the edge of a square or any other shape.

An advantage of the 2-axis gimbal system employed in the fourth embodiment is that the axes of the two rotation stages intersect, and their intersection can be arranged to coincide with the centre of the plate, which enables a relatively compact system. In other variants of the fourth embodiment, other configurations of rotation stages may be alternatively used for rotating the plate about mutually orthogonal axes of rotation that do not intersect or are close to the centre of the plate. With the 2-axis gimbal system, the second axis of rotation rotates with rotation about the first axis. It is though preferable that the second axis remains substantially orthogonal to the direction of the beam during the exposure; in particular, it is preferable that it remains orthogonal to within ±25°, and most preferably to within ±15°, otherwise the magnitude of the transverse displacement of the beam illuminating the photomask produced by rotation of the plate about the second axis may be unacceptably reduced.

In another variant of the fourth embodiment, an alternative 2-axis gimbal system is employed in which the two axes are mutually orthogonal and are uncoupled, i.e. the axis of one stage is not rotated by the other stage. The system is configured in the DTL exposure system such that both axes of the gimbal system are orthogonal to the direction of the beam (and remain orthogonal to the beam) as the plate is rotated about each axis. In terms of resulting contrast of the time-integrated intensity distribution illuminating the photomask, such a decoupled 2-axis gimbal system generally has negligible advantage with respect to the off-the-shelf gimbal system described above.

Whereas a single plate is angularly displaced about at least one axis of rotation in each of the embodiments and variants thereof described above, in other embodiments two or a larger number of plates may alternatively be angularly displaced. For example, with reference to FIG. 6 which illustrates a sixth embodiment of the invention, the single plate of the first embodiment is substituted by a pair of plates 6a, 6b whose surfaces have the same area as that of the single plate and whose combined thickness is the same as the thickness of the single plate. The plates are arranged sequentially in the beam, i.e. in a stack, are preferably mutually parallel and with a separation that is preferably small in relation to the plate thickness to facilitate their mounting to the rotation stage. The two plates are separated by a distance 0.5 mm using a spacer 8a in the form of a sheet of material with a large central aperture, which is interposed between the plates. The modified system is employed in the same manner as the first embodiment, the lateral offset of the beam transmitted by the pair of plates being similarly calculated using equ. (2) except that the parameter T refers instead to the combined thickness of the plates (excluding the spacing between them). Such a substitution of a single plate by a pair, or larger number, of plates may be applied to any of the other earlier embodiments. For multi-plate embodiments it is more important that the surfaces of the plates are anti-reflection coated in order that the exposure time does not become too long.

In other multi-plate embodiments, the additional plate(s) may be mounted instead to additional rotation stage(s) that rotate the additional plate(s) during the exposure about the same or different axis or axes of rotation as the first plate.

Whereas each of the embodiments above describes and illustrates the application of the present invention to the particular photolithographic technique of Displacement Talbot Lithography, in other embodiments the same methodology for reducing localized intensity inhomogeneities in the beam may be employed with other Talbot-effect-based lithographic techniques such as achromatic Talbot lithography and conventional Talbot-imaging lithography, or alternatively with other photolithographic techniques that require the illumination of a periodic pattern in a mask by a well-collimated and monochromatic beam, for example, near-field holographic lithography.

For the former, Talbot-effect-based techniques both the apparatus for reducing localized intensity inhomogeneities can also be the same because the exposure beam illuminates the photomask at normal incidence.

For near-field holographic lithography, however, the exposure beam needs to illuminate the mask at an oblique angle such that only two diffracted orders propagate in desired directions after the mask (as described earlier). In this case, the apparatus of the various embodiments need to be reconfigured so that beam transmitted by the rotating plate illuminates the photomask at the required angle of incidence. In particular the orientation of the photomask, photoresist-coated substrate and associated mechanical sub-system needs to be arranged in relation to that of the combination of illumination and rotating plate(s) modules so that the beam transmitted by the rotating plate illuminates the photomask at the required oblique angle of incidence.

For near-field holography the separation between the photosensitive layer on the substrate and the periodic pattern in the photomask needs to be sufficiently small in order that the range of angles of incidence of the light within the collimated beam illuminating each point of the photomask does not cause unacceptable blurring, or smearing, of the periodic intensity distribution illuminating the photosensitive layer, i.e. the same consideration as previously described for Talbot-imaging-based photolithography. The photosensitive layer on the substrate therefore needs to be correspondingly arranged in proximity to the periodic pattern in the photomask in relation to the degree of collimation of the illuminating beam and the period of the pattern in the photomask so that the periodic pattern printed into the photosensitive layer has the desired contrast.

In variants of this embodiment based on near-field holography, the grating in the mask may be an amplitude grating in the form of chrome lines on a transparent mask substrate such as fused silica, or advantageously a phase grating, as is often used in the prior art, or alternatively a volume grating in which the lines and spaces are formed as regions of different refractive index in a suitable photosensitive recording material.

Moreover, in these and the earlier embodiments, the photosensitive layer into which the second periodic pattern is printed during the exposure is preferably a positive-tone or negative-tone photoresist, which is subsequently developed after the exposure to remove the respectively exposed or unexposed areas. The photosensitive layer may alternatively be another type of material, for instance, one that records a periodic variation of exposure energy density as a periodic variation, or modulation, of refractive index, as is typically the case for a holographic recording material.

In other variants of the earlier embodiment, each of the two surfaces of the plate are instead coated with a partially reflecting coating that provides, for example, ˜50% reflectivity and ˜50% transmission per surface. With such coatings the transmission of the plate for the directly transmitted beam is ˜25%, and a part of the incident beam's power is double reflected between the 2 surfaces of the plate before being transmitted in the same direction as the directly transmitted beam, contributing an additional ˜6% to the plate's overall transmission. With an oblique angle of incidence of the beam on the plate, the double-reflected component of the transmitted beam is laterally offset (by a distance proportional to each of the angle of incidence and the plate's thickness) with respect to the directly transmitted component. The superposition of the two laterally offset components reduces the instantaneous contrast of the local intensity homogeneities, thereby further reducing the contrast of the inhomogeneities in the time-integrated intensity distribution illuminating the photomask. Whereas the illumination wavelength employed in the embodiments above is in the near-UV part of the spectrum and the photoresist employed is sensitive to this wavelength, in other embodiment of the invention the illumination wavelength may be in another part of the spectrum, such as visible, deep-UV, in particular 248 nm or 193 nm, or extreme-UV, and the photoresist employed should be appropriately selected so that they have the sensitivity required for the wavelength concerned.

Although the parallel-sided plates described in the embodiments above are all formed of fused silica, it should be understood that in other embodiments the plates may be formed of other materials that are similarly transparent or partially transparent to the wavelength of the illumination beam concerned. For example, certain borosilicate glasses have a high transmission down to ˜360 nm would be good alternatives to fused silica for a near-UV exposure wavelength, and UV-grade calcium fluoride would be an alternative material for a deep-UV exposure wavelength. A glass with a low transmission to the illumination wavelength may be alternatively used but with the disadvantage of a longer exposure time.

1-21. (canceled)

22. A method for improving the uniformity of exposure of a first periodic pattern in a photomask by a collimated beam in a photolithographic system using the Talbot effect to print a second periodic pattern into a photosensitive layer on a substrate in proximity to the photomask, the method comprising:
a) providing a plate composed of a material transparent to the beam, the plate having opposing surfaces being mutually parallel and separated by a thickness;
b) placing the plate in the photolithographic system such that the beam illuminates the plate at an initial angle of incidence and a beam transmitted by the plate illuminates the photomask; and
c) rotating the plate through at least one angle about at least one axis of rotation during the exposure such that the transmitted beam displaces translationally across the photomask.

23. The method according to claim 22, which further comprises rotating the plate about an axis of rotation perpendicular to a direction of the beam.

24. The method according to claim 22, which further comprises placing the plate such that the beam illuminates the plate at an oblique initial angle of incidence and rotating the plate about an axis of rotation parallel to a direction of the beam.

25. The method according to claim 22, which further comprises placing the plate such that the beam illuminates the plate at an oblique initial angle of incidence, and rotating the plate firstly through a first angle about a first axis of rotation parallel to a direction of the beam, secondly through a second angle about a second axis of rotation perpendicular to the beam, and thirdly through a third angle about the first axis of rotation.

26. The method according to claim 22, which further comprises placing the plate such that the beam illuminates the plate at an oblique initial angle of incidence and rotating the plate simultaneously through a first angle about a first axis of rotation parallel to a direction of the beam and through a second angle about a second axis of rotation perpendicular to the beam.

27. The method according to claim 22, which further comprises rotating the plate about first and second axes of rotation being mutually orthogonal and substantially perpendicular to a direction of the beam.

28. The method according to claim 22, which further comprises:
rotating the plate about first and second axes of rotation being mutually orthogonal and substantially perpendicular to a direction of the beam;
describing time-dependencies of the rotations about the first and second axes by respective sine and cosine functions; and
keeping a magnitude of the angle of incidence of the beam on the plate substantially constant during the exposure.

29. The method according to claim 22, which further comprises selecting the initial angle of incidence or setting the initial angle of incidence within a selected range of angles of incidence.

30. The method according to claim 22, which further comprises selecting the thickness of the plate, the initial angle of incidence and the at least one angle about the at least one axis of rotation, to produce a desired displacement of the transmitted beam across the photomask.

31. The method according to claim 22, which further comprises starting the rotation of the plate before the exposure of the photomask.

32. The method according to claim 22, which further comprises providing at least one additional plate composed of a material transparent to the beam, placing the at least one additional plate in the photolithographic system such that the transmitted beam illuminates the at least one additional plate and the beam transmitted by the at least one additional plate illuminates the photomask, and rotating the at least one additional plate about at least one axis of rotation during the exposure.

33. An apparatus for improving the uniformity of exposure of a periodic pattern in a photomask by a collimated beam in a photolithographic system using the Talbot effect to print a second periodic pattern into a photosensitive layer on a substrate in proximity to the photomask, the apparatus comprising:
a) a plate composed of a material transparent to the beam, said plate having mutually parallel opposing surfaces separated by a thickness;
b) said plate being placed in the photolithographic system such that the beam illuminates said plate at an initial angle of incidence and a beam transmitted by said plate illuminates the photomask; and
c) said plate being rotated through at least one angle about at least one axis of rotation during the exposure such that the transmitted beam displaces translationally across the photomask.

34. The apparatus according to claim 33, wherein said plate rotates about an axis of rotation perpendicular to a direction of the beam.

35. The apparatus according to claim 33, wherein said plate is disposed such that the beam illuminates said plate at an oblique initial angle of incidence and said plate rotates about an axis of rotation parallel to a direction of the beam.

36. The apparatus according to claim 33, wherein said plate is disposed such that the beam illuminates said plate at an oblique initial angle of incidence, and said plate is rotated firstly through a first angle about a first axis of rotation parallel to a direction of the beam, secondly through a second angle about a second axis of rotation perpendicular to the beam, and thirdly through a third angle about the first axis of rotation.

37. The apparatus according to claim 33, wherein said plate is rotated simultaneously about a first axis parallel to a direction of the beam and about a second axis perpendicular to the beam.

38. The apparatus according to claim 33, wherein said plate is rotated about first and second axes of rotation being mutually orthogonal and substantially perpendicular to a direction of the beam.

39. The apparatus according to claim 33, wherein said plate is rotated about each of first and second axes of rotation being mutually orthogonal and substantially perpendicular to a direction of the beam, time-dependencies of the rotations about the first and second axes are described respectively by sine and cosine functions, and a magnitude of the angle of incidence of the beam on the plate remains substantially constant during the exposure.

40. The apparatus according to claim 33, wherein the beam is monochromatic, and a distance between the photomask and the substrate being photoresist-coated and disposed in proximity to the photomask is varied during the exposure according to the method of Displacement Talbot Lithography.

41. A method for improving the uniformity of exposure of a first periodic pattern in a photomask by a collimated beam of monochromatic light in a photolithographic system printing a second periodic pattern into a photosensitive layer on a substrate in proximity to the photomask, the method comprising:
a) providing a plate composed of a material transparent to the beam, the plate having opposing surfaces being mutually parallel and separated by a thickness;
b) placing the plate in the photolithographic system such that the beam illuminates the plate at an initial angle of incidence and a beam transmitted by the plate illuminates the photomask; and
c) rotating the plate through at least one angle about at least one axis of rotation during the exposure such that the transmitted beam displaces translationally across the photomask.

42. An apparatus for improving the uniformity of exposure of a first periodic pattern in a photomask by a collimated beam of monochromatic light in a photolithographic system printing a second periodic pattern into a photosensitive layer on a substrate in proximity to the photomask, the apparatus comprising:
a) a plate composed of a material transparent to the beam, said plate having opposing surfaces being mutually parallel and separated by a thickness;
b) said plate being placed in the photolithographic system such that the beam illuminates said plate at an initial angle of incidence and a beam transmitted by said plate illuminates the photomask; and
c) said plate being rotated through at least one angle about at least one axis of rotation during the exposure such that the transmitted beam displaces translationally across the photomask.
